(19) United States
(12) Patent Application Publication
(10) Pub. No.: US 2023/0217548 A1
(43) Pub. Date: Jul. 6, 2023

(54) METHODS AND APPARATUS FOR HEATING AND TEMPERATURE MONITORING

(71) Applicant: ASM IP Holding B.V., Almere (NL)

(72) Inventor: Ankit Kimtee, Phoenix, AZ (US)

(21) Appl. No.: 18/089,635

(22) Filed: Dec. 28, 2022

Related U.S. Application Data
(60) Provisional application No. 63/295,487, filed on Dec. 30, 2021.

(51) Int. Cl. H05B 1/02; H05B 3/20

(52) U.S. Cl. CPC H05B 1/0233; H05B 1/0244; H05B 3/20; H05B 2203/013; H05B 2203/016; H05B 2203/005; H01L 21/67248

(57) ABSTRACT

An apparatus may provide a component, such as a showerhead, a pipe, a valve manifold, or a vessel, having a printed heater affixed to an outer surface of the component. In addition, a printed temperature sensor may be affixed to the outer surface of the component. The apparatus may further provide a controller to control the power to the printed heater according to data output from the printed temperature sensor.

### CROSS-REFERENCE TO RELATED APPLICATIONS

This application is a nonprovisional of, and claims priority to and the benefit of, U.S. Provisional Patent Application No. 63/295,487, filed Dec. 30, 2021 and entitled “METHODS AND APPARATUS FOR HEATING AND TEMPERATURE MONITORING,” which is hereby incorporated by reference herein.

### FIELD OF INVENTION

The present disclosure generally relates to methods and apparatus for heating and temperature monitoring. More particularly, the present disclosure relates to methods and apparatus for heating and temperature monitoring in equipment used to fabricate semiconductor devices.

### BACKGROUND OF THE DISCLOSURE

Various components of a system used for fabricating semiconductor devices may need constant temperature regulation. A heating source may be applied to the component in cases where a temperature above room temperature is desired. Alternatively, a cooling source may be applied to the component in cases where a temperature below room temperature is desired. In many applications, heater jackets are used as the heating source, and the heater jackets wrap around the component. The heater jackets, however, are bulky and may not provide sufficient heating or thermal uniformity to the component due to inconsistent contact with the components.

The system may also include temperature sensors to monitor the actual temperature of the heated or cooled component. In many cases, the information from the temperature sensor is used to control the operation of the heating source or the cooling source to regulate the temperature of the component. However, conventional temperature sensors may suffer from contact mismatch or misplacement, which may result in inaccurate temperature readings and, thus, undesired operation of the heating or cooling source and poor temperature regulation of the component.

### SUMMARY OF THE DISCLOSURE

An apparatus may provide a component, such as a showerhead, a pipe, a valve manifold, or a vessel, having a printed heater affixed to an outer surface of the component. In addition, a printed temperature sensor may be affixed to the outer surface of the component. The apparatus may further provide a controller to control the power to the printed heater according to data output from the printed temperature sensor.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 representatively illustrates a system in accordance with an exemplary embodiment of the present technology;

FIG. 2 is an exploded view of a printed heater in accordance with an exemplary embodiment of the present technology;

FIG. 3 is a cross-sectional view of a printed heater in accordance with various embodiments of the present technology;

FIG. 4 is a cross-sectional view of an alternative printed heater in accordance with various embodiments of the present technology;

FIG. 5 is an apparatus in accordance with a first embodiment of the present technology;

FIG. 6 is an apparatus in accordance with a second embodiment of the present technology;

FIG. 7 is an apparatus in accordance with a third embodiment of the present technology;

FIG. 8 is an apparatus in accordance with a fourth embodiment of the present technology; and

FIG. 9 is a cross-sectional view of an apparatus in accordance with a fifth embodiment of the present technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

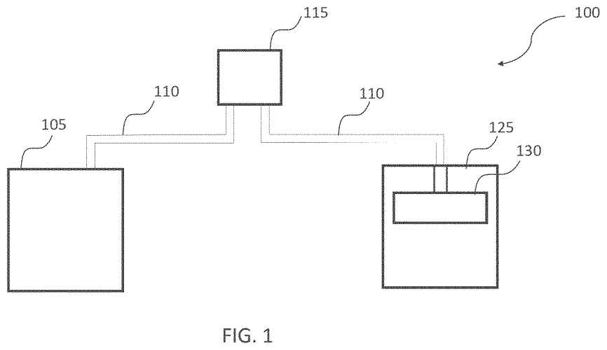

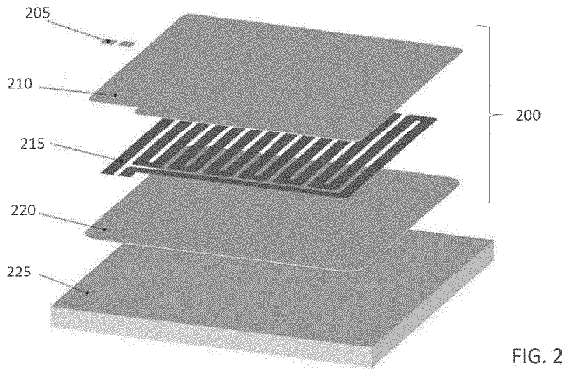

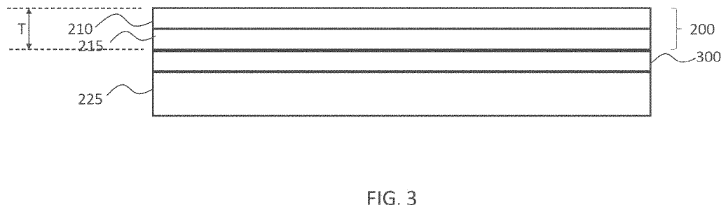

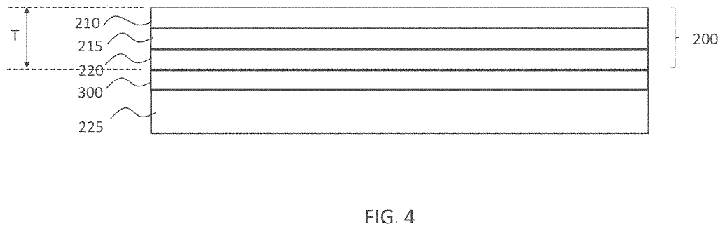

Reference will now be made to the drawings wherein like reference numerals identify similar structural features or aspects of the subject disclosure. For purposes of explanation and illustration, and not limitation, a partial view of an example of semiconductor processing system in accordance with the present disclosure is shown in FIG. 1 and is designated generally by reference character 100. Other examples of semiconductor processing systems in accordance with the present disclosure, or aspects thereof, are provided in FIGS. 2-9, as will be described. The methods and apparatus of the present disclosure may be used for regulating a temperature of one or more components of a semiconductor processing system using a heating source and a temperature sensor, though the present disclosure is not limited to use in semiconductor processing.

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

The present disclosure generally relates to a printed heater affixed to an outer surface of a component used in a semiconductor processing system. In addition, some aspects of the present technology are generally related to a printed temperature sensor affixed to an outer component used in a semiconductor processing system.

Referring to FIG. 1, a system 100 may comprise a vessel 105 to contain a chemical (such as a liquid or gas), a pipe 110, a valve assembly 115, and a showerhead 130.

In various embodiments, and referring to FIGS. 1-9, the system 100 may further comprise a temperature regulation system configured to monitor and/or regulate the temperature of various components in the system 100. In various embodiments, the temperature regulation system may comprise a printed heater 200. The printed heater 200 may comprise a first dielectric layer 200, a conductive layer 215, and a second dielectric layer 210. In various embodiments, the printed heater 200 may further comprise a solder pad 205 used to electrically connect the printed heater 200 to a peripheral system or device (not shown). In an exemplary embodiment, the first dielectric layer 220 may directly overlie a component 225 (e.g., the vessel 105, the pipe 110, the valve assembly 115, and the showerhead 130) of the system 100. In various embodiments, the printed heater 200 may be configured to generate a temperature in the range of 10 degrees Celsius to 250 degrees Celsius.

In various embodiments, the printed heater 200 may be affixed on an outer surface of the component 225. For example, the printed heater 200 may be printed directly on the outer surface of the component 225. Alternatively, the printed heater 200 may be attached to the outer surface of the component 225 with an adhesive layer 300 arranged directly between the component and the printed heater 200. In various embodiments, the printed heater 200 may be a low-profile heater having a total thickness T in the range of 0.1 mm to approximately 10 millimeters. The printed heater 200 may have a width of 1 to 10 millimeters, or any suitable dimensions. The length and width of the printed heater 200 may be any suitable dimension and may be selected according to the application site.

In various embodiments, the second dielectric layer 220 may comprise any suitable insulating material and/or non-conductive material, such as a plastic. In some embodiments, the second dielectric layer 220 may be formed directly on an outer surface of the component 225 using any suitable method. Alternatively, the second dielectric layer 220 may be adhered to the outer surface of the component 225 with the adhesive layer 300. The second dielectric layer 220 may have a thickness in the range of 0.1 mm to approximately 5 millimeters.

In various embodiments, the conductive layer 215 may comprise any suitable conducting material, such as a conducting metal (e.g., copper). In various embodiments, the conductive layer 215 may overlie the second dielectric layer 220. Alternatively, the conductive layer 215 may be deposited directly on the outer surface of the component 225. Alternatively, the conductive layer 215 may be adhered to the outer surface of the component 225 with the adhesive layer 300. The conductive layer 215 may have any suitable pattern, such as a serpentine pattern, a comb-shaped pattern, a spiral pattern, and the like. The conductive layer 215 may have a thickness in the range of 0.1 mm to approximately 5 millimeters. In various embodiments, the conductive layer 220 may be electrically connected to the solder pad 205.

In various embodiments, the first dielectric layer 210 comprise an insulating material and/or non-conductive material, such as a plastic and may overlie the conducting layer 215. The first dielectric layer 210 may have a thickness in the range of 0.1 mm to approximately 5 millimeters.

In various embodiments, the printed heater 200 may operate according to a control signal.

In various embodiments, the temperature regulation system may further comprise a temperature sensor 600, such as a printed thermocouple, configured to detect temperature and generate an output sensor signal Vout corresponding to the detected temperature. In various embodiments, the temperature sensor 600 may be affixed on an outer surface of the component 225. For example, the temperature sensor 600 may be printed directly on the outer surface of the component 225. Alternatively, the temperature sensor 600 may be attached to the outer surface of the component 225 with an adhesive layer 300 arranged directly between the component and the temperature sensor 600. In various embodiments, the temperature sensor 600 may be a low-profile sensor having a thickness in the range of 0.1 millimeters to 10 millimeters.

In various embodiments, the temperature sensor 600 may comprise a first leg formed from a first material, such as nickel, chromium, aluminum or a combination thereof, and a second leg formed from a second material, such as nickel, chromium, aluminum, or a combination thereof. The first material may be different from the second material. For example, the first material may be Ni₂OCr while the second material may be Ni₅Al.

In addition, the temperature sensor 600 may be embedded within or covered with a thermal coating (not shown). The thermal coating may comprise one or more layers of any suitable material, such as yttria stabilized zirconia.

In various embodiments, the system 100 may further comprise a processor 610 or other suitable control system configured to receive the sensor signal Vout. The processor 610 may respond to the sensor signal Vout by generating a control signal to increase/decrease the temperature of the heating source in order to heat the component 225 to a desired temperature. In various embodiments, the processor 610 may receive and respond to the sensor signal Vout to control the temperature of the printed heater 200. In addition or alternatively, the processor 610 may receive and respond to the sensor signal Vout to control the temperature of a different heating source, such as a heater jacket 605.

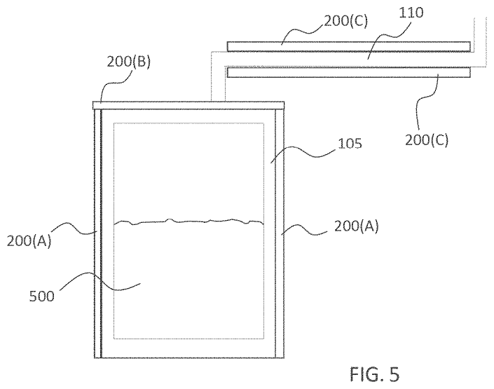

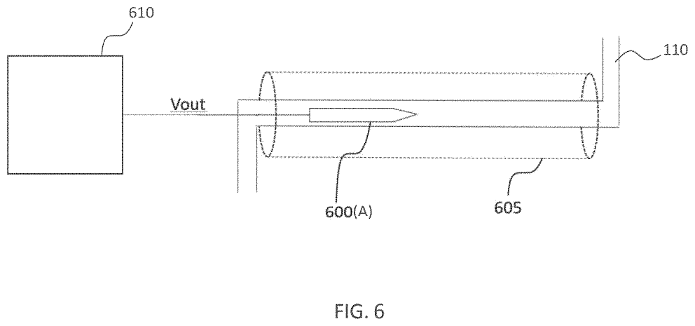

In an exemplary embodiment, and referring to FIGS. 5 and 6, the temperature sensor 600 and/or the printed heater 200 may be affixed or adhered to an outer surface of the vessel 105. In the present case, a plurality of printed heaters, such as a first printed heater 200(A) and a second printed heater 200(B), may be affixed or adhered to the vessel 105. The first printed heater 200(A) may surround the outer sidewalls of the vessel 105 and the second printed heater 200(B) may cover an outer surface of a top of the vessel 105. In the present embodiment, the first and second printed heaters 200(A), 200(B) may be configured to generate a temperature in the range of 10 to 150 degrees Celsius.

The first and second printed heaters 200(A), 200(B) may be connected to and controlled by the processor 610 (FIG. 6). The processor 610 may control the first and second printed heaters 200(A), 200(B) according to a temperature sensor, such as the temperature sensor 600.

Similarly, a third printed heater 200(C) may be affixed or adhered to the pipe 110 that connects to the vessel 105. In the present case, the printed heater 200(C) may wrap around the outer surface of the pipe 110. The third printed heater 200(C) may be connected to and controlled by the processor 610 (FIG. 6). The processor 610 may control the third printed heater 200(C) according to a temperature sensor, such as the temperature sensor 600. In the present embodiment, the third printed heater 200(C) may be configured to generate a temperature in the range of 45 to 150 degrees Celsius.

In an exemplary embodiment, and referring to FIG. 6, a first temperature sensor 600 may be affixed or adhered to the outer surface of the pipe 110. In the present case, the first temperature sensor 600 may be used in conjunction with the heater jacket 605. Accordingly, the temperature sensor 600 may generate the sensor signal Vout and transmit the signal to the processor 610. The processor 610 may then control the operation of the heater jacket 605 according to the sensor signal and a desired temperature of the component (in this case, the pipe 110).

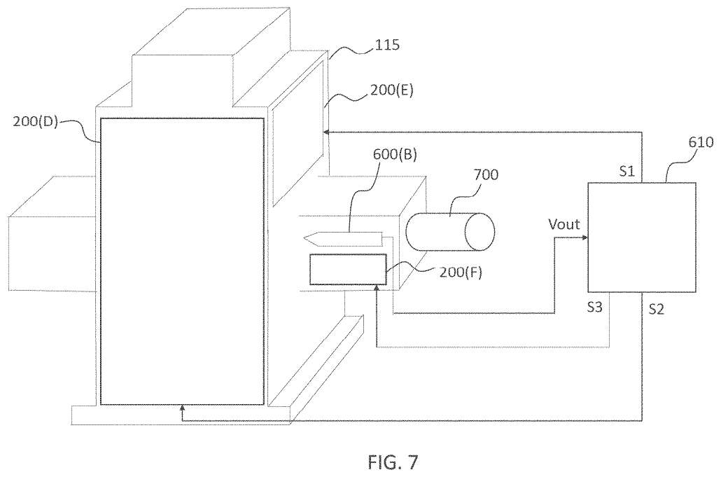

In an exemplary embodiment, and referring to FIG. 7, the temperature sensor 600 and/or the printed heater 200 may be affixed or adhered to the outer surfaces of the valve assembly 115. For example, in the present case, a fourth printed heater 200(D) is affixed to a first sidewall, a fifth printed heater 200(E) is affixed to a second sidewall that is perpendicular to the first sidewall, and sixth printed heater 200(F) is affixed to adjacent to an inlet/outlet pipe 700. In the present embodiment, the fourth and fifth printed heaters 200(D), 200(E) may be configured to generate temperature in the range of 90 to 250 degrees Celsius.

In addition, the temperature sensor 600 may be located on the outer surface of the valve assembly that is adjacent to the inlet/outlet pipe 700. The inlet/outlet pipe 700 may be attached to or continuous with the pipe 110.

In various embodiments, the valve assembly 115 may be configured to open and close according to an electrical signal or by a mechanical mechanism. For example, the valve assembly 115 may comprise a pneumatically-controlled valve, a solenoid-controlled valve, or any suitable valve control style. In addition, the valve assembly 115 may comprise a diaphragm valve, plug valve, needle valve, or the like. The particular valve type may be selected according to the particular application and/or system. For example, a particular valve may be more suitable for a particular application based on the valve specifications, such as flow rate, temperature rating, pressure rating, and the like.

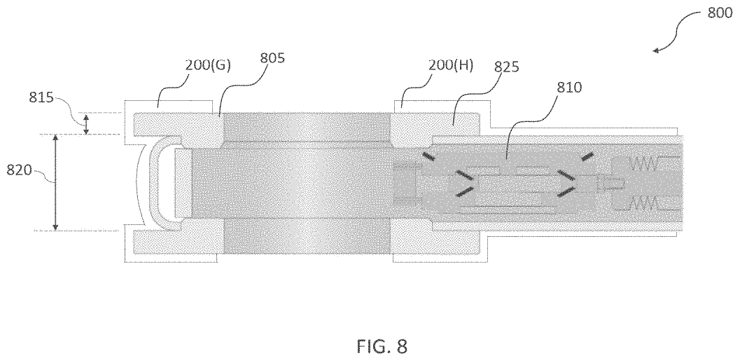

In an exemplary embodiment, and referring to FIG. 8, the valve assembly 115 may comprise a gate valve 800. The printed heater 200 may be affixed or adhered to portion of the gate valve 800. For example, a seventh printed heater 200(G) may be affixed or adhered to a first portion 805 of the gate valve 800 and an eighth printed heater 200(H) may be affixed or adhered to a second portion 825 of the gate valve 800. The seventh and eighth printed heaters 200(G), 200(H) may be controlled independently from each other by the processor 610 (FIG. 6). Alternatively, the seventh and eighth printed heaters 200(G), 200(H) may be controlled simultaneously. In other words, the seventh and eighth printed heaters 200(G), 200(H) may be electrically connected and receive the same control signal from the processor 610. Furthermore, the seventh and eighth printed heaters 200(G), 200(H) may be controlled independently from other printed heaters in the system 100, such as the first, second, and/or third printed heaters 200(A), 200(B), 200(C). Alternatively, the seventh and eighth printed heaters 200(G), 200(H) may be controlled simultaneously with one or more of the other printed heaters 200 in the system 100.

In the present embodiment, the seventh printed heater 200(G) may be applied to small features and/or spaces with a tight clearance. For example, the seventh printed heater 200(G) may be continuous across a region comprising a feature having a height 815 and a clearance space 820 between two features. In other embodiments, the printed heater 200 may be continuous across a region comprising a feature having a height 815 and/or a clearance space 820.

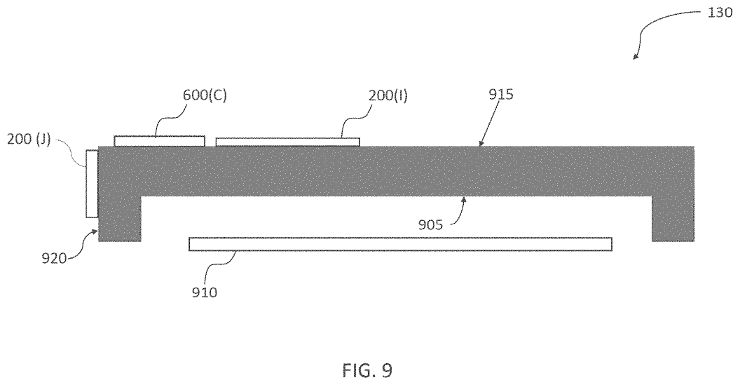

In an exemplary embodiment, and referring to FIG. 9, the temperature sensor 600 and/or the printed heater 200 may be affixed or adhered to the outer surfaces of the showerhead 130. The showerhead 130 may comprise a downward facing surface 905 that faces a substrate 910, an outward facing surface 915 that is opposite the downward facing surface 905, and a sidewall surface 920. The downward facing surface 905 may comprise a plurality of apertures (not shown) that direct vapor to the surface of the substrate 910. The outward facing surface 915 and the sidewall surfaces 920 may be substantially flat with a smooth, uniform surface.

In the present case, the temperature sensor 600(C) and/or the printed heater 200 may be affixed or adhered to the outward facing surface outer surface 915 and the sidewall surface 920 of the showerhead 130. The printed heater 200 may be a single, continuous element, such that the entirety of the printed heater 200 heats at the same degree.

Alternatively, a number of printed heaters 200 may be affixed or adhered to the outward facing surface 915 and/or the sidewall surface 920, wherein each printed heater 200 is independently-controlled relative to the other printed heaters on the showerhead 130. In such a case, one printed heater 200(I) may heat to a first temperature while another printed heater 200(J) may heat to a second temperature that is different from the first temperature. Controlling the temperature of each printed heater independently may provide a more uniform thermal pattern of the showerhead 130, and thus a more uniform chemical deposition on the substrate 910. In the present embodiment, the printed heaters 200(I), 200(J) may be configured to generate a temperature in the range of 90 to 250 degrees Celsius.

In some embodiments, information from the temperature sensor 600(C) may be used to control an adjacent printed heater, such as printed heater 200(I). Similarly, a different temperature sensor (not shown) may be used to control the printed heater 200(J).

In operation, and referring to FIGS. 1-9, various embodiments of the present technology may provide a closed-loop system for temperature regulation of various components in an integrated system. For example, the temperature sensor 600 may be used to detect a temperature of the component that it is attached to and generate a corresponding sensor signal Vout. The sensor signal Vout may be transmitted to the processor 610. The processor 610 may analyze and/or convert the sensor signal, for example to a digital signal.

In response to the sensor signal Vout, the processor 610 may generate one or more output control signals, such as a first control signal S1 and a second control signal S2, and transmit the control signal to one or more printed heaters 200 and/or other suitable heating sources, such as a heater jacket 605 and the like. For example, in some cases, each printed heater 200 may be independently controlled relative to other printed heaters 200 in the system 100. In the present case, each printed heater 200 may be controlled according to a temperature sensor 600 that corresponds to the respective printed heater and/or is physically adjacent to the respective printed heater. For example, the printed heater 200(F) may be controlled by the second temperature sensor 600(B), while the fourth and fifth printed heaters 200(D), 200(E) may be controlled by a sensor signal from a different printed temperature sensor (not shown). In other words, in this case, the control signals S1 and S2 would have different values.

In other cases, two or more printed heaters 200 may be controlled according to the same control signal and a signal sensor signal Vout. For example, the fourth and fifth printed heaters 200(D), 200(E) may be controlled by a sensor signal from a same (shared) temperature sensor 600. In other words, in this case, the control signals S1 and S2 would have the same value.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

1. An apparatus, comprising:
a component comprising at least one of a showerhead, a pipe, a valve manifold, and a vessel;
a printed heater affixed on an outer surface of the component and configured to heat the component;
a printed temperature sensor affixed on the surface of the component and configured to measure an actual temperature of the component and generate a corresponding temperature signal, wherein the printed temperature sensor is positioned adjacent to the printed heater; and
a controller connected to the printed temperature sensor and the printed heater, and configured to control power to the printed heater according to the temperature signal.

2. The apparatus of claim 1, wherein the showerhead comprises:
a first surface comprising a plurality of apertures; and
a second surface, opposite-facing from the first surface, and comprising a smooth, uniform surface;
wherein the printed heater is affixed on at least a portion of the smooth, uniform surface.

3. The apparatus of claim 1, wherein the printed heater has a thickness in the range of 0.1 millimeters to 10 millimeters and the printed temperature sensor has a thickness in the range of 0.1 millimeters to 10 millimeters.

4. The apparatus of claim 1, wherein the printed heater is configured to generate a temperature in the range of 10 degrees Celsius to 250 degrees Celsius.

5. The apparatus of claim 1, wherein the pipe is configured to flow one of a gas or a liquid, and the printed heater is configured to generate a temperature in the range of 45 to 150 degrees Celsius.

6. The apparatus of claim 1, wherein the vessel is configured to contain one of a gas or a liquid, and the printed heater is configured to generate a temperature in the range of 10 to 150 degrees Celsius.

7. The apparatus of claim 1, further comprising an adhesive layer directly between the surface of the component and the printed heater.

8. The apparatus of claim 1, wherein the printed heater comprises a metal electrode affixed to the surface of the component and a dielectric layer overlying the metal electrode.

9. A method for regulating a temperature of a component, comprising:
heating the component with a printed heater, wherein the component comprises at least one of a showerhead, a vessel, a pipe, and a valve manifold, and wherein the heater affixed to the surface of the component; and
monitoring the temperature of the component with a printed temperature sensor, wherein the printed temperature sensor is positioned adjacent to the printed heater;
generating, with the printed temperature sensor, actual temperature data of the component;
regulating an operation of the printed heater in response to the actual temperature data.

10. The method of claim 9, wherein the printed heater has a thickness in the range of 0.1 millimeters to 10 millimeters and the printed temperature sensor has a thickness in the range of 0.1 millimeters to 10 millimeters.

11. The method of claim 9, wherein the printed heater is configured to generate a temperature in the range of 10 degrees Celsius to 250 degrees Celsius.

12. The method of claim 9, wherein the printed heater and the printed temperature sensor are affixed to the surface of the component with an adhesive layer.

13. A system, comprising:
a vessel configured to contain one of a gas or liquid;
a valve manifold connected to the vessel via a pipe;
a showerhead connected to the valve manifold and configured to deliver a source chemical to a reaction chamber;
a first printed heater affixed on an outer surface of the showerhead;
a second printed heater affixed on an outer surface of the pipe;
a third printed heater affixed on the outer surface of the valve manifold;
a fourth printed heater affixed on the outer surface of the vessel;
a first printed temperature sensor affixed on the outer surface of the showerhead;
a second printed temperature sensor affixed on the outer surface of the pipe;
a third printed temperature sensor affixed on the outer surface of the valve manifold; and
a fourth printed temperature sensor affixed on the outer surface of the vessel;
wherein the printed temperature sensor is positioned adjacent to the printed heater.

14. The system of claim 13, wherein each of the first, second, third, and fourth printed heaters are operated independently from the others.

15. The system of claim 13, wherein the first printed heater is configured to generate a temperature in the range of 90 to 250 degrees Celsius.

16. The system of claim 13, wherein the second printed heater is configured to generate a temperature in the range of 45 to 150 degrees Celsius.

17. The system of claim 13, wherein the third printed heater is configured to generate a temperature in the range of 90 to 250 degrees Celsius.

18. The system of claim 13, wherein the fourth printed heater is configured to generate a temperature in the range of 10 to 150 degrees Celsius.

19. The system of claim 13, wherein the showerhead comprises:
a first surface comprising a plurality of apertures; and
a second surface, opposite-facing from the first surface, and comprising a smooth, uniform surface;
wherein the printed heater is affixed on at least a portion of the smooth, uniform surface.

20. The system of claim 13, wherein each of the first, second, third, and fourth printed heaters are affixed on the outer surface with a respective adhesive layer; wherein the each of the first, second, third, and fourth printed temperature sensors are affixed on the outer surface with a respective adhesive layer.
